(19) United States
(12) Patent Application Publication
(10) Pub. No.: US 2010/0174968 A1
(43) Pub. Date: Jul. 8, 2010

(54) HEIRARCHICAL ERASURE CODING

(75) Inventors: Denis X. Charles, Redmond, WA (US); Siddhartha Puri, Sammamish, WA (US); Reid Marlow Andersen, La Jolla, CA (US)

Correspondence Address: MICROSOFT CORPORATION, ONE MICROSOFT WAY, REDMOND, WA, 98052, US

(73) Assignee: MICROSOFT CORPORATION, Redmond, WA (US)

(21) Appl. No.: 12/348,072

(22) Filed: Jan. 2, 2009

(51) Int. Cl. H03M 13/15; G06F 15/16; G06F 11/10

(52) U.S. Cl. 714/781; 709/204; 714/E11.032

(57) ABSTRACT

Arrangements are provided for efficient erasure coding of files to be distributed and later retrieved from a peer-to-peer network, where such files are broken up into many fragments and stored at peer systems. The arrangements further provide a routine to determine the probability that the file can be reconstructed. The arrangements further provide a method of performing the erasure coding in an optimized fashion, allowing fewer occurrences of disk seeks.

### BACKGROUND

Peer-to-peer “p2p” distributed storage and delivery systems are highly useful in providing scalability, self-organization, and reliability. Such systems have demonstrated the viability of p2p networks as media for large-scale storage applications. In particular, p2p networks can be used to provide backup for files if the data is stored redundantly at the peers.

A p2p network is a popular environment for streaming data. A p2p network is one in which peer machines are networked together and maintain the state of the network via records on the participant machines. In p2p networks, any end host can initiate communications, and thus p2p networks are also sometimes referred to as “endhost” networks. Typical p2p networks generally lack a central server for administration, although hybrid networks do exist. Thus, generally speaking, the term p2p refers to a set of technologies that allows a group of computers to directly exchange data and/or services. The distinction between p2p networks and other network technologies is more about how the member computers communicate with one another than about the network structure itself. For example, end hosts in a p2p network act as both clients and servers in that the both consumer data and serve data to their peers.

In p2p distributed file sharing, pieces of a file are widely distributed across a number of peers. Then whenever a client requests a download of that file, that request is serviced from a plurality of peers rather then directly from the server. For example, one such scheme, referred to as “Swarmcast™,” spreads the load placed on a web site offering popular downloadable content by breaking files into much smaller pieces. Once a user has installed the Swarmcast client program, their computers automatically cooperate with other users' computers by passing around (i.e., serving) pieces of data that they have already downloaded, thereby reducing the overall serving load on the central server. A similar scheme, BitTorrent®, works along very similar principles. In particular, when under low load, a web site which serves large files using the BitTorrent scheme will behave much like a typical http server since it performs most of the serving itself. However, when the server load reaches some relatively high level, BitTorrent will shift to a state where most of the upload burden is borne by the downloading clients themselves for servicing other downloading clients. Schemes such as Swarmcast and BitTorrent are very useful for distributing pieces of files for dramatically increasing server capacity as a function of the p2p network size.

The mechanisms used by such schemes may vary. In the simplest case, a subject file may be copied many times, each time onto a different peer. This approach is wasteful since the amount of extra storage required to store these copies is sub-optimal. A more space-optimal approach employs erasure codes. Erasure codes are codes that work on any erasure channel (a communication channel that only introduces errors by deleting symbols and not altering them). In this approach, e.g., a file F is separated into fragments F₁, F₂, . . . , Fₖ. A a coding scheme is applied to these fragments that produces new fragments E₁, E₂, . . . , Eₙ, where n>k, with the property that retrieving any k out of the n fragments Eᵢ is sufficient to reconstruct the file. The coding cost of this approach is 0(n/F/) word operations for the encoding and 0(k³+k/F/) for the decoding. For most practical purposes k and n are of similar order so this generally forces the number of fragments generated n to be small.

It is sometimes difficult in practical p2p backup schemes to keep the number of fragments small, because if the number of fragments is, e.g., 100 and the original file is of size 10 Gb, then each fragment is 100 Mb long. It is generally unlikely that a peer would be online long enough for a 100 Mb fragment to be uploaded to it. This encourages the use of smaller fragments; however, these in turn make the coding and decoding costs prohibitive.

One approach to get around the problem is to separate the large file F into a number of smaller files F₁, . . . , Fₘ and then erasure code each one of these files. But this has the disadvantage that, to reconstruct the file F, it is necessary to reconstruct F₁, then reconstruct F₂, . . . , and finally reconstruct Fₘ. The probability that all of these reconstructions are successful becomes very attenuated when m gets moderate.

This Background is provided to introduce a brief context for the Summary and Detailed Description that follow. This Background is not intended to be an aid in determining the scope of the claimed subject matter nor to be viewed as limiting the claimed subject matter to implementations that solve any or all of the disadvantages or problems presented above.

### SUMMARY

The arrangements presented here provide for storing and delivering files in a p2p system using hierarchical erasure coding. In other words, the erasure coding is performed in hierarchical stages. At the first stage, the original file is erasure coded or otherwise broken up into a first plurality of fragments. At the second stage, each of the first plurality is erasure coded to produce a second plurality of fragments. Successive stages are performed similarly. The process may be visualized as a tree whose root is the original file, and whose leaves are the fragments that are eventually streamed to a peer. The leaves may be streamed in a random fashion to peers.

The arrangements also provide a way to evaluate the failure probability of a file. That is, the probability, given a number of peers and their respective availabilities that the original file will not be able to be faithfully reconstructed. The failure probability may be calculated using a recursive algorithm that may depend on the property that each peer should receive a random leaf in the hierarchical erasure-coding scheme.

The arrangements further provide a disk-efficient process of streaming fragments. An encoded file is created which is a transpose representation of that created in the usual encoding process. In this way, a single pass through the file can generate the fragment that will be sent to a peer. To produce a random leaf in a hierarchical encoding, enough top-level bytes are read to be able to produce an initial segment of a random child of the root, and the process may continue inductively until the entire leaf has been read.

This Summary is provided to introduce a selection of concepts in a simplified form. The concepts are further described in the Detailed Description section. Elements or steps other than those described in this Summary are possible, and no element or step is necessarily required. This Summary is not intended to identify key features or essential features of the claimed subject matter, nor is it intended for use as an aid in determining the scope of the claimed subject matter. The claimed subject matter is not limited to implementations that solve any or all disadvantages noted in any part of this disclosure.

### BRIEF DESCRIPTION OF THE DRAWINGS

FIG. 1 illustrates the decomposition or deconstruction, e.g., by erasure coding, of a subject file into a plurality of fragment files, and the subsequent erasure coding of the plurality of fragment files into higher-order pluralities of fragment files.

FIG. 2 illustrates a network arrangement in which a subject system is communicatively coupled to a plurality of peer systems, i.e., a p2p system.

FIG. 3 illustrates a flowchart of an arrangement for erasure coding, the arrangement erasure coding a file in a hierarchical manner.

FIG. 4 illustrates a flowchart of an arrangement for calculating a failure probability, the failure probability corresponding to the probability that a subject file, erasure-coded in a hierarchical manner with leaves stored randomly at a plurality of peer systems, will not be able to be reconstructed, generally due to offline peers.

FIG. 5 illustrates a data flow diagram among modules of the arrangement for hierarchical erasure coding.

FIG. 6 illustrates a data flow diagram among modules of the arrangement for calculating a failure probability.

FIG. 7 illustrates steps in performing a file transposition to allow optimized disk usage during fragment file creation and distribution.

FIG. 8 is a simplified functional block diagram of an exemplary configuration of an operating environment in which the arrangement for hierarchical erasure coding may be implemented or used.

Corresponding reference characters indicate corresponding parts throughout the drawings.

### DETAILED DESCRIPTION

Arrangements are provided for hierarchical erasure coding of files for p2p backup and other purposes. A probabilistic estimate may be calculated for the likelihood of successfully reconstructing the file from online peers. The arrangements may perform the erasure coding in a disk-efficient manner.

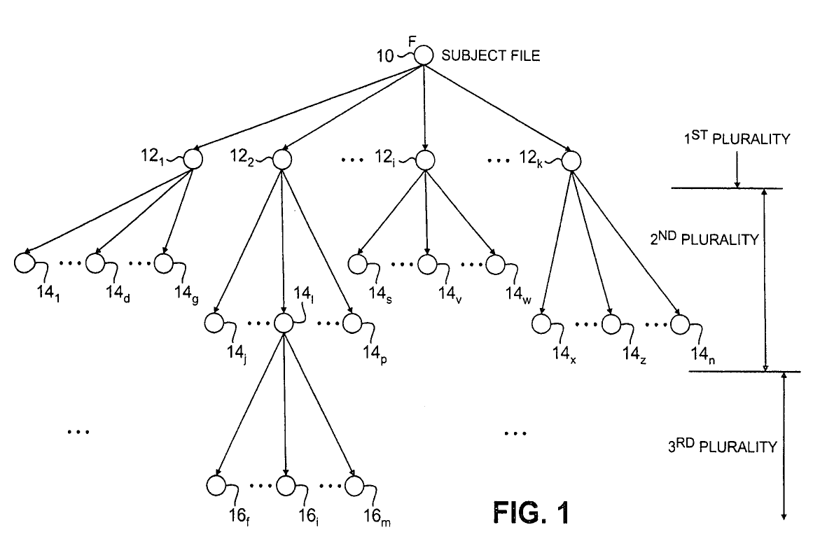

FIG. 1 illustrates a decomposition of a subject file 10 (“F”) into a first plurality k of fragment files 12₁-12ₖ. In one implementation, the subject file maybe encoded using an erasure-coding algorithm. As the arrangement has such algorithms already built-in, the same may be conveniently used for this purpose; however, other algorithms may also be employed to create the k fragment files of the first plurality. FIG. 1 also indicates a further deconstruction of the first plurality k of fragment files 12₁-12ₖ into a second plurality n of fragment files 14₁-1ₙ, where n>k This represents a “zeroth” order erasure coding of fragment files. Of course, if the first plurality k was created using erasure coding, then the creation of the second plurality n is actually the second use of an erasure coding routine in the arrangement. The arrangement may further include yet another erasure coding of the previously erasure-coded fragment files 14₁-14ₙ. In FIG. 1, this further erasure coding routine is indicated by a third plurality m of fragment files 16₁-16ₘ, where m>n.

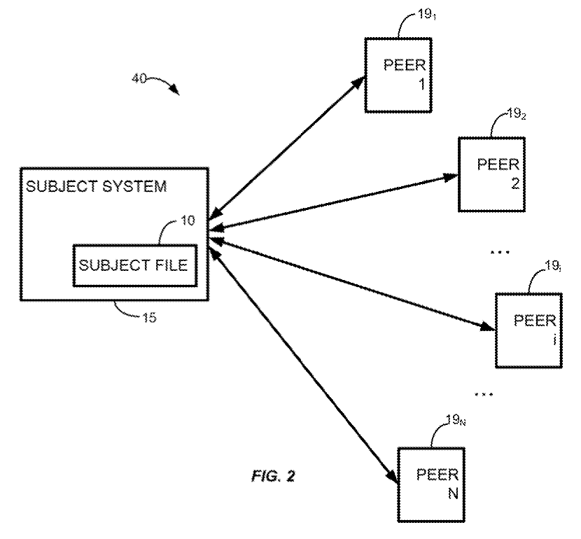

Referring to FIG. 2, a network arrangement 40 is illustrated in which a subject system 15 is communicatively coupled to a plurality of peer systems 1-N, with corresponding reference numerals 19₁-19_{N}, i.e., a p2p network. The subject file 10 is also illustrated. The subject file 10 is that which will undergo decomposition, e.g., by erasure coding, and the resulting file fragments will then undergo another step of erasure coding prior to be transmitted for storage by peers 1-N. At a time of retrieval, a subset of peers 1-N, i.e., the peers that are online at a later time, will then be requested to transmit their fragment file, e.g., back to the subject system 15, for reconstruction. In an erasure-coding system, not all peers that received file fragments need be online for a file to be fully reconstructed, due to the redundancy in data introduced by the erasure coding. It is further noted that each peer may receive multiple fragment files.

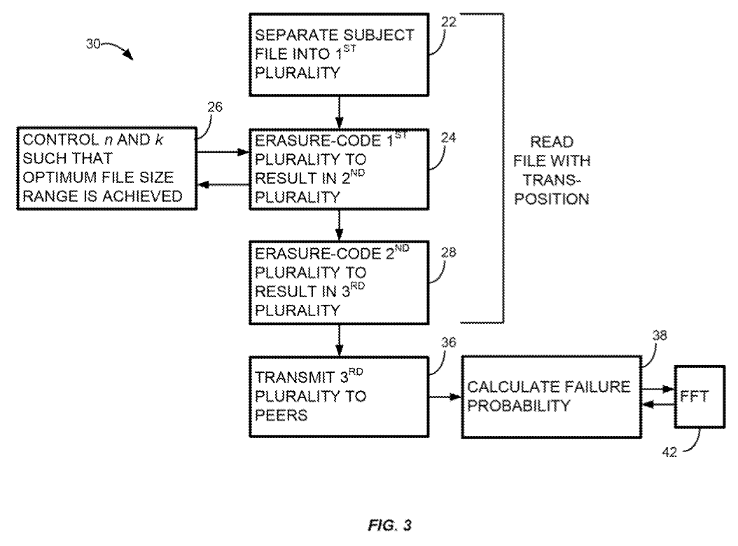

FIG. 3 illustrates a flowchart 30 of an arrangement for erasure coding, the arrangement erasure coding a file in a hierarchical manner. A first step is that the subject file is decomposed, deconstructed, or in some other manner separated into a first plurality of file fragments, also known as fragment files or just “fragments” (step 22). Each of the first plurality is then erasure-coded to result in a second plurality of fragments (step 24). If necessary, the files of the second plurality may then be erasure-coded to result in a third plurality of fragments (step 28). These steps may be repeated any number of times until an optimum file size range is reached (step 26). The optimum file size range may vary, but may be generally chosen such that a peer may be expected to be online, i.e., connected over a network to the subject system, for a long enough time in a typical session that the fragment file may be re-transmitted back to the subject system without disconnection.

According to the arrangement described above, the erasure coding is performed in hierarchical stages. At stage 0, the subject file F=F⁰ is erasure coded into fragment files F₁⁰, . . . Fₙ⁰. The parameters n and k of the erasure coding may be chosen such that the stage 0 decomposition can be performed rapidly. At later stages, e.g., at stage t, each fragment Fᵢ^{t-1} is erasure coded to produce Fᵢ^{t}. In this way, after t stages, n^{t} fragments will have been produced, each of size

$$\frac{\vert F \vert}{{k}^{t}} .$$

The process may be visualized as a tree whose root is the subject file F and whose leaves are the fragments that are eventually streamed to a peer. It is noted that only leaves may be distributed to peers, and a single peer may store multiple leaves.

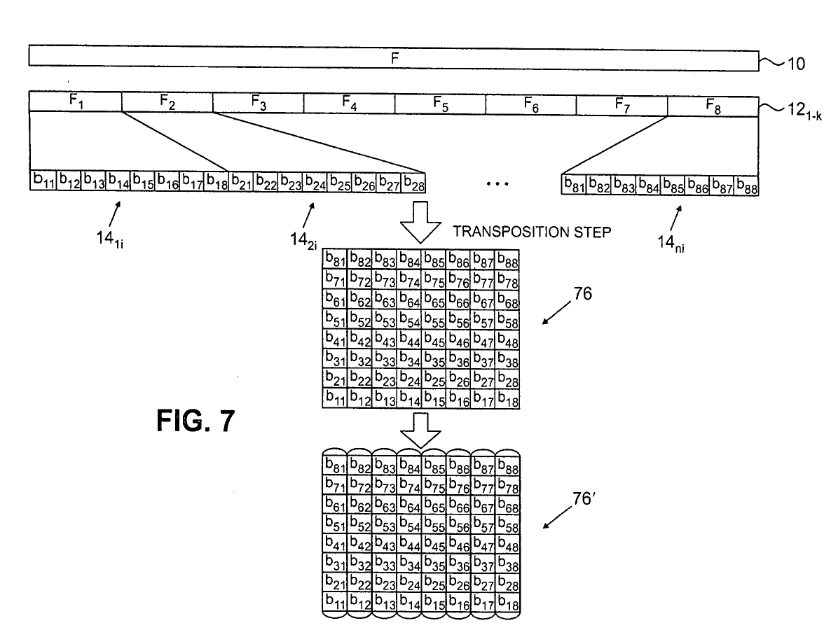

Any of the erasure-coding steps may include a step of reading the subject file or fragment files in a transposed manner (step 34) so as to reduce the number of disk seeks, thus allowing the reading to be performed in a disk-efficient way. One way of implementing this reading in a transposed manner is described below in connection with FIG. 7.

The last-created plurality of fragment files is then transmitted to the peer systems (step 36). A failure probability may be calculated and displayed at any time subsequent to construction of the final plurality (step 38), and the calculation may include use of a Fourier Transform (e.g., a fast Fourier transform or “FFT”) (step 42).

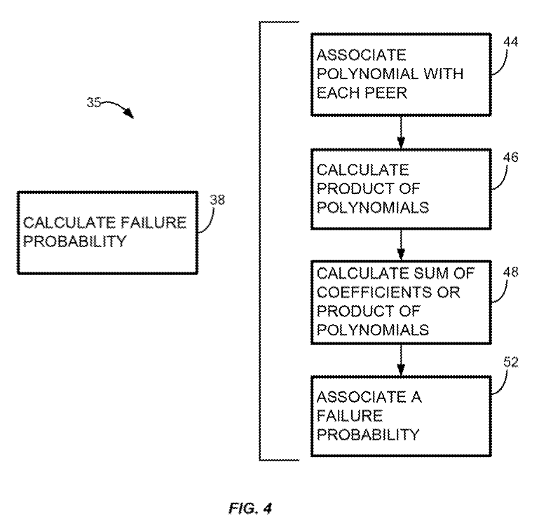

FIG. 4 illustrates a flowchart 35 of an arrangement for calculating a failure probability. The failure probability corresponds to the probability that a subject file, erasure-coded in a hierarchical manner with leaves stored at a plurality of peer systems, will not be able to be reconstructed, generally due to offline peers. It will be understood that the failure probably is highly related to a success probability, the latter being a likelihood that the subject file will be able to be reconstructed. In general:

success probability=1−failure probability

So if a system calculates one it is trivial to calculate the other.

To outline this arrangement, the failure probability calculation includes a first step of associating a polynomial with each peer (step 44). A next step is to calculate a product of these polynomials (step 46). A sum is then calculated of the coefficients of the product of the polynomials (step 48). Finally, a failure probability is associated with the result of the summing step (step 52).

This arrangement is described below in additional detail. A subject file F is separated into a first plurality of fragment files F₀, F₁, . . . , Fₖ₋₁. These k fragment files are erasure-coded into n fragments E₀, E₁, . . . , Eₙ₋₁. Collecting any k of these fragments allows the reconstruction of the subject file F. It is noted above that the hierarchical erasure-coding arrangement may employ multiple erasure-coding steps. For simplicity and clarity, the calculation of failure probability will be described with respect to the Eᵢ. It will be understood that the arrangement may apply similarly to any order of erasure-coded Eᵢ.

Eᵢ is transmitted to a peer Pᵢ, and the likelihood that Pᵢ is online is pᵢ. The algorithm for computing the failure probability also assumes that the events that Pᵢ being online is independent of the probability that any other peer or set of peers is online. Generally if this assumption is not true, then one cannot determine the failure probability in anything less than exponential time in the number of peers constituting the p2p network. With multiple steps of erasure-coding, n may be caused to rise and the file fragment size may be caused to decrease.

For each Pᵢ, a polynomial is associated Pᵢ(X)=qᵢ+pᵢX, where qᵢ=1−pᵢ. For the first polynomials:

P₁(X)=q₀+p₀X

P₀(X)P₁(X)=q₀q₁+(q₀p₁+q₁p₀)X+p₀p₁X²

Etc.

Thus in general P(X) may be expressed as a polynomial:

$$P ( X ) = {\prod }_{0 \leq i \leq n}^{ } {P}_{i} ( X ) = {a}_{0} + {a}_{1} X + … + {a}_{i} {X}^{i} + … + {a}_{n} {X}^{n}$$

In this case, αᵢ, the coefficient of Xⁱ, is the probability that exactly i peers are online. As k files are needed for reconstruction, the probability is then the sum of these coefficients, up to the k^{th} term:

$${\sum }_{0 \leq i \leq k}^{ } {a}_{i}$$

It may be calculated that the probability of failure with n peers can be determined in a time on the order of n²[0(n²)].

However, if a file is first deconstructed into k fragments and those fragments are then erasure coded into n fragments, such that the i^{th} peer Pᵢ receives tᵢ fragments, then the polynomial becomes:

$$P ( X ) = {\prod }_{0 \leq i \leq n}^{ } ( {q}_{i} + {p}_{i} {X}^{{t}_{i}} )$$

The sum of the coefficients of this polynomial of the terms X^{r} for r<k gives the failure probability for reconstruction of the subject file. The computation of this product can be performed in less time than 0(n²); rather, it may be performed in a time 0(n log²(n)). In particular, it can be shown that, given two polynomials f and g of degree n, their product may be computed in a time 0(n log n) using an FFT. And a corollary to this is that:

$$P ( X ) = {\prod }_{0 \leq i \leq n}^{ } ( {q}_{i} + {p}_{i} {X}^{{t}_{i}} )$$

may be computed in a time 0(n log²(n)), again employing the FFT.

The time saved is significant. The following table demonstrates the significant time savings achieved when using the transform method:

| | FFT | Naïve, e.g., non- |
|---|---|---|
| N | [sec] | transform [sec] |
| 9000 | 0.55 | 0.61 |
| 100,000 | 8.94 | 90.62 |

As noted above, the erasure coding may be performed such that n and k are not too large, as this tends to increase the time cost of encoding. In particular, the encoding time is 0(nk/Fᵢ/), while the decoding time is 0(k³+k²/Eᵢ/). In the same way, fragment sizes may generally not be too large, as a peer will not likely be online long enough for a fragment to be transferred in either direction.

In one implementation, the failure probability may be calculated as below. First it is noted that if erasure coding is applied with the same parameters of (n,k) to each level, then the probability that the file can be reconstructed in part depends on how the leaves are distributed. If the assignment of leaves is performed arbitrarily, then the probability requires exponential time. However, if the assignment of leaves is performed randomly, then significantly less time may be required.

If Pᵢ is available with probability pi and the same stores tᵢ fragments, then:

Pr[t_fragments_available]=coeffₓ_{^{t}}, (π(qᵢ+pᵢX^{t}^{ᵢ}))

The table of these probabilities may be calculated in a time 0(n_{f} log²(n_{f})), where n_{f} is the number of fragments. Correspondingly, a balls-in-bins analysis, it can be shown that:

Aₜ=Pᵣ [File can be recovered|t fragments online]

can be computed in a time 0(hn_{f}² log²(n_{f})) where h is the height of the tree, i.e., number of levels of erasure-coding that were performed.

Thus Pr[File can be recovered]=ΣₜAₜPr[t fragments available] which was provided above. By using other techniques, e.g., concentration results, one can calculate even better approximations to this probability, e.g., in a time 0(hn_{f}^{1.5} log²(n_{f})).

For higher levels of encoding, the method generalizes in a straightforward manner by mathematical induction.

While the description above describes a process whereby a probability is calculated given a set of parameters, e.g., n and k, it should be noted that the converse relationship may also be employed. For example, given that a user desires a 99% chance of reconstructing the file, the process may be employed to calculate how many fragments need to be generated to accomplish this goal.

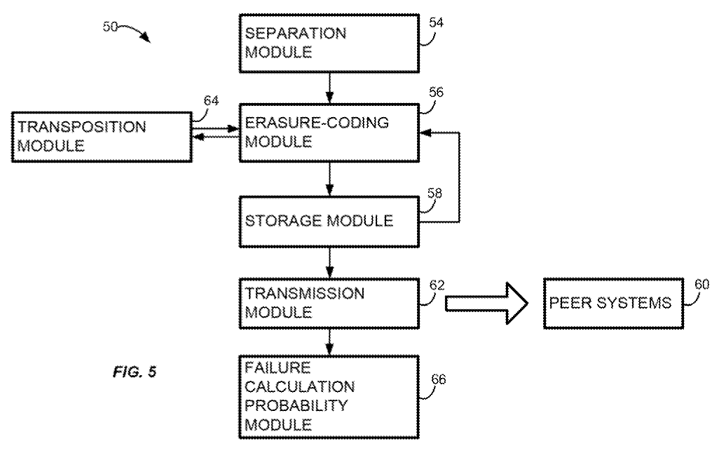

For hierarchical erasure coding of files, the arrangement 50 of FIG. 5 may be implemented. A separation module 54 serves to perform the initial decomposition of the subject file into fragments. An erasure-coding module 56 then erasure codes each fragment formed. As noted above, the erasure-coding module may also perform the initial step of deconstructing the subject file. A transposition module 64 may be employed to make more efficient the scheme of reading and erasure-coding fragment files, as is discussed below in connection with FIG. 7. A storage module 58 may store any of the first, second, third, or subsequent pluralities of fragment files, as well as the subject file. In some implementations, the fragments may not be stored, but rather may be streamed to peers as soon as created.

A transmission module 62 transmits the fragments to the peer systems 60, and this may be performed using any manner of transmission, including streaming as soon as created, storing and then transmitting the fragment, or the like. Finally, a failure probability calculation module 66 may be employed to determine the likelihood, or not, of being able to reconstruct the subject file.

For the reconstruction of the subject file, it is noted that each of the erasure-coded leaves also has as meta-data the name of the leaf. When the fragments are received, they are deposited into the appropriate leaf. As soon as enough fragments have been received to reconstruct a leaf, the leaf is reconstructed and a higher-level fragment is thus obtained. This process may proceed level-by-level in this fashion until the root level is decoded. Note that to perform a successful decoding, one must remember the tree structure that was used to encode the file in the first place. This is not a copious amount of data if a regular structure like a full tree is used with the same branching factor at each level.

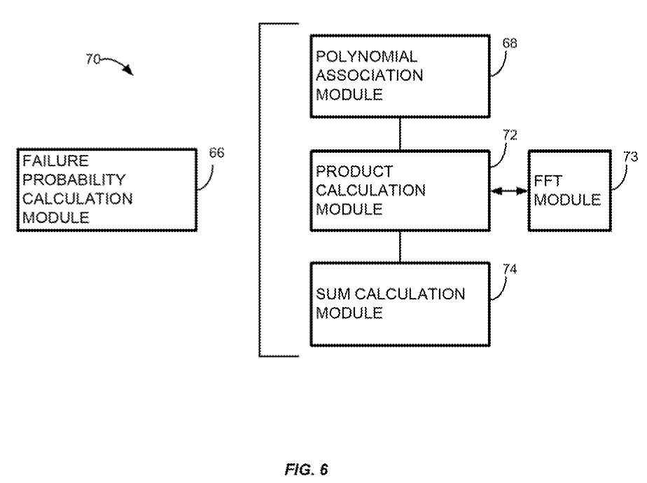

FIG. 6 illustrates details of the failure probability calculation module 66, including modules which may be employed to perform the calculations noted above. A polynomial association module 68 serves to associate a polynomial with each peer system. A product calculation module 72 calculates a product of the polynomials, and in so doing may employ a Fourier transform module 73, the same performing, e.g., fast Fourier transforms. A sum calculation module 74 may perform a sum of the polynomial coefficients to obtain a value related to the failure probability.

FIG. 7 illustrates steps in performing a file transposition to allow optimized disk usage during fragment file distribution. The subject file 10 is deconstructed into a first plurality of files 12₁-k. Each file of the first plurality is then erasure coded, creating a second plurality 14₁₋ₙ, each constituting a number of data segments bᵢⱼ, which may be bytes, words, or any other segment.

To perform erasure coding, the fragments generally include parts of each section of the file, e.g., a part of F₁, a part of F₂, etc. To read from each section requires multiple and non-optimum disk seeks. For example, to construct the first erasure-coded fragment E₁, each bᵢ₁ would have to be examined, requiring n time-consuming disk seeks. If instead the file is re-interpreted as representing b₁₁, . . . , bₙ₁, b₁₂, . . . bₙ₂, b₁₃, . . . , bₙ₃, . . . , b₁ₘ, . . . , bₙₘ, as shown by array 76, then E1 can be generated by reading the first portion of the file, i.e., reading consecutive bytes without seeking, as shown by the columns depicted in array 76′. This technique may be applied at multiple levels of the erasure coding tree. In some instances, the technique may involve re-writing the transposed version onto the disk.

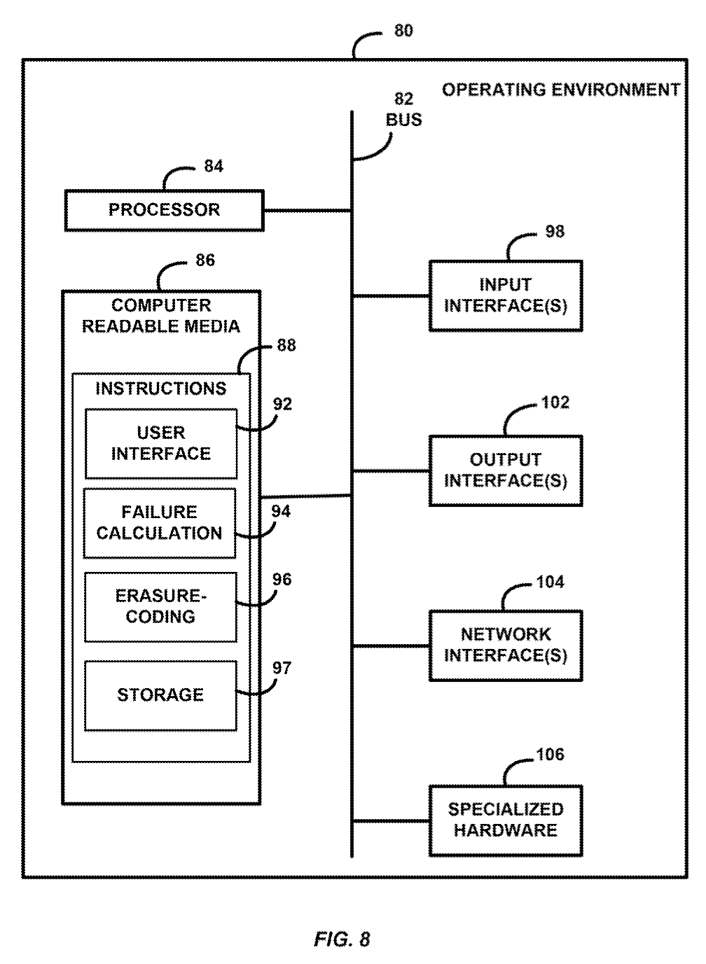

FIG. 8 is a block diagram of an exemplary configuration of an operating environment 80 in which all or part of the arrangements and/or methods shown and discussed in connection with the figures may be implemented or used For example, the operating environment may be employed in the subject system or any of the peer systems or both. Operating environment 80 is generally indicative of a wide variety of general-purpose or special-purpose computing environments, and is not intended to suggest any limitation as to the scope of use or functionality of the arrangements described herein.

As shown, operating environment 80 includes processor 84, computer-readable media 86, and computer-executable instructions 88. One or more internal buses 82 may be used to carry data, addresses, control signals, and other information within, to, or from operating environment 80 or elements thereof.

Processor 84, which may be a real or a virtual processor, controls functions of the operating environment by executing computer-executable instructions 88. The processor may execute instructions at the assembly, compiled, or machine-level to perform a particular process.

Computer-readable media 86 may represent any number and combination of local or remote devices, in any form, now known or later developed, capable of recording, storing, or transmitting computer-readable data, such as computer-executable instructions 88 which may in turn include user interface functions 92, failure calculation functions 94, erasure-coding functions 96, or storage functions 97. In particular, the computer-readable media 86 may be, or may include, a semiconductor memory (such as a read only memory (“ROM”), any type of programmable ROM (“PROM”), a random access memory (“RAM”), or a flash memory, for example); a magnetic storage device (such as a floppy disk drive, a hard disk drive, a magnetic drum, a magnetic tape, or a magneto-optical disk); an optical storage device (such as any type of compact disk or digital versatile disk); a bubble memory; a cache memory; a core memory; a holographic memory; a memory stick; a paper tape; a punch card; or any combination thereof. The computer-readable media may also include transmission media and data associated therewith. Examples of transmission media/data include, but are not limited to, data embodied in any form of wireline or wireless transmission, such as packetized or non-packetized data carried by a modulated carrier signal.

Computer-executable instructions 88 represent any signal processing methods or stored instructions. Generally, computer-executable instructions 88 are implemented as software components according to well-known practices for component-based software development, and are encoded in computer-readable media. Computer programs may be combined or distributed in various ways. Computer-executable instructions 88, however, are not limited to implementation by any specific embodiments of computer programs, and in other instances may be implemented by, or executed in, hardware, software, firmware, or any combination thereof.

Input interface(s) 98 are any now-known or later-developed physical or logical elements that facilitate receipt of input to operating environment 80.

Output interface(s) 102 are any now-known or later-developed physical or logical elements that facilitate provisioning of output from operating environment 80.

Network interface(s) 104 represent one or more physical or logical elements, such as connectivity devices or computer-executable instructions, which enable communication between operating environment 80 and external devices or services, via one or more protocols or techniques. Such communication may be, but is not necessarily, client-server type communication or p2p communication. Information received at a given network interface may traverse one or more layers of a communication protocol stack.

Specialized hardware 106 represents any hardware or firmware that implements functions of operating environment 80. Examples of specialized hardware include encoders/decoders, decrypters, application-specific integrated circuits, clocks, and the like.

The methods shown and described above may be implemented in one or more general, multi-purpose, or single-purpose processors.

Functions/components described herein as being computer programs are not limited to implementation by any specific embodiments of computer programs. Rather, such functions/components are processes that convey or transform data, and may generally be implemented by, or executed in, hardware, software, firmware, or any combination thereof.

It will be appreciated that particular configurations of the operating environment may include fewer, more, or different components or functions than those described. In addition, functional components of the operating environment may be implemented by one or more devices, which are co-located or remotely located, in a variety of ways.

Although the subject matter herein has been described in language specific to structural features and/or methodological acts, it is also to be understood that the subject matter defined in the claims is not necessarily limited to the specific features or acts described above. Rather, the specific features and acts described above are disclosed as example forms of implementing the claims.

It will further be understood that when one element is indicated as being responsive to another element, the elements may be directly or indirectly coupled. Connections depicted herein may be logical or physical in practice to achieve a coupling or communicative interface between elements. Connections may be implemented, among other ways, as inter-process communications among software processes, or inter-machine communications among networked computers. The word “exemplary” is used herein to mean serving as an example, instance, or illustration. Any implementation or aspect thereof described herein as “exemplary” is not necessarily to be constructed as preferred or advantageous over other implementations or aspects thereof.

As it is understood that embodiments other than the specific embodiments described above may be devised without departing from the spirit and scope of the appended claims, it is intended that the scope of the subject matter herein will be governed by the following claims.

What is claimed is:

1. A computer-readable medium, comprising instructions for causing a processor in an electronic device to perform a method of hierarchical erasure coding, the method comprising:
a. receiving a maximum fragment size;
b. separating a subject file into a first plurality of fragment files;
c. erasure coding each file of the first plurality to produce a second plurality of fragment files, the second plurality greater than or equal in number than a number of the first plurality, the erasure coding performed such that the subject file is capable of being reconstructed using a certain number of the second plurality of fragment files, the certain number greater than or equal to the number of the first plurality;
d. erasure coding each file of the second plurality to produce a third plurality of fragment files, the third plurality greater in number than a number of the second plurality, the erasure coding performed such that the subject file is capable of being reconstructed using another certain number of the third plurality of fragment files, the another certain number greater than or equal to the number of the second plurality;
e. repeating the erasure-coding step until a final plurality of fragment files is produced, each of the final plurality having a file size less than the maximum fragment size; and
f. transmitting each of the final plurality to a respective peer computing device in a p2p network.

2. The computer-readable medium of claim 1, in which the transmitting is performed such that the respective peer computing devices in the p2p network each receive a random fragment file of the final plurality, and in which the method further comprises calculating a failure probability for recovery of the subject file.

3. The computer-readable medium of claim 2, in which the calculating a failure probability for recovery of the subject file includes:
a. associating a polynomial with each peer having a file of the final plurality;
b. calculating a product of the polynomials associated with each peer;
c. calculating a sum of a plurality of coefficients of the product of the polynomials; and
d. associating a failure probability for recovery of the subject file with the calculated sum.

4. The computer-readable medium of claim 3, in which the calculating a product is performed using a FFT.

5. The computer-readable medium of claim 1, in which any erasure coding includes reading the respective fragment files in a transposed fashion, such that at least one datum from each fragment may be read consecutively.

6. The computer-readable medium of claim 5, further comprising:
a. creating an initial segment of each fragment file from the reading;
b. performing the transmitting step using the created initial segment; and
c. repeating the reading, creating and performing for each file in the respective plurality.

7. The computer-readable medium of claim 1, in which the receiving a maximum fragment size includes receiving a maximum fragment size from a location in memory.

8. The computer-readable medium of claim 1, in which the receiving a maximum fragment size includes receiving a maximum fragment size from a user input.

9. The computer-readable medium of claim 2, in which the transmitting is performed such that at least one respective peer computing device in the p2p network receives more than one random fragment file of the final plurality.

10. A computer-readable medium, comprising instructions for causing a processor in an electronic device to perform a method of calculating a value related to a probability of reconstructing a file following a process of hierarchical erasure coding and distribution of a resulting plurality of fragment files to a plurality of peers in a peer-to-peer network, the method comprising:
a. associating a polynomial with each peer;
b. calculating a product of the polynomials associated with the peers; and
c. summing the coefficients of the product of the polynomials.

11. The medium of claim 10, in which the calculating is performed using a FFT.

12. The medium of claim 10, in which the plurality of fragment files are distributed to a plurality of peers in a random fashion.

13. A computer-readable medium, comprising instructions for causing a processor in an electronic device to perform a method of hierarchical erasure coding, the method comprising:
a. separating a subject file into a first plurality of fragment files;
b. erasure-coding each file of the first plurality to produce a second plurality of fragment files, the second plurality greater in number than a number of the first plurality, the erasure-coding performed such that the subject file is capable of being reconstructed using a certain number of the second plurality of fragment files, the certain number greater than or equal to the number of the first plurality;
c. such that the erasure coding includes reading the fragment files of the first plurality in a transposed fashion, such that at least one datum from each fragment may be read consecutively; and
d. transmitting each of the second plurality to a respective peer computing devices in a peer-to-peer network.

14. The medium of claim 13, in which the transmitting is performed in a random fashion.

15. The medium of claim 13, further comprising receiving a maximum fragment size.

16. The medium of claim 15, further comprising repeating the erasure-coding step until a final plurality of fragment files is produced, each of the final plurality having a file size less than or equal to the maximum fragment size.

17. The medium of claim 15, in which the receiving a maximum fragment size includes receiving a user input indicating the maximum fragment size.

18. The medium of claim 13, further comprising calculating a failure probability for recovery of the subject file.

19. The medium of claim 13, in which the calculating a failure probability for recovery of the subject file includes:
a. associating a polynomial with each peer having a file of the second plurality;
b. calculating a product of the polynomials associated with each peer;
c. calculating a sum of a plurality of coefficients of the product of the polynomials; and
d. associating a failure probability for recovery of the subject file with the calculated sum.

20. The medium of claim 19, in which the calculating a product is performed using a FFT.
